(19) United States
(12) Patent Application Publication
(10) Pub. No.: US 2026/0033190 A1
(43) Pub. Date: Jan. 29, 2026

(54) DISPLAY SCREEN AND ELECTRONIC DEVICE

(71) Applicant: Lenovo (Beijing) Limited, Beijing (CN)

(72) Inventors: Liqin ZHANG, Beijing (CN); Jue WANG, Beijing (CN)

(21) Appl. No.: 19/344,787

(22) Filed: Sep. 30, 2025

Related U.S. Application Data
(63) Continuation of application No. PCT/CN2023/135473, filed on Nov. 30, 2023.

(30) Foreign Application Priority Data
Mar. 31, 2023 (CN) 202320696173.6

(51) Int. Cl. H10K 59/131

(52) U.S. Cl. CPC H10K 59/131

(57) ABSTRACT

A display screen includes: a body, having a first surface including a display output area; and a connection terminal, where the display screen includes M data lines, each corresponding to a column in N display pixel units forming the display output area; the M data lines are arranged to form a first width; each data line corresponds to a connection line; the M connection lines are arranged to form a second width, the second width being smaller than the first width; the M connection lines are arranged on the display output area; the M connection lines extend from the body at the second width and are connected to the connection terminal; the M connection lines are deformable, and both M and N are greater than or equal to 1.

### CROSS-REFERENCE TO RELATED APPLICATION(S)

This application claims priority to PCT International Application No. PCT/CN2023/135473 filed on Nov. 30, 2023, which in turn claims priority to Chinese Patent Application No. 202320696173.6 filed on Mar. 31, 2023, both of which are incorporated herein by reference in their entireties.

### FIELD OF THE TECHNOLOGY

The present disclosure relates to a technical field of electronic devices, and in particular to a display screen and electronic device.

### BACKGROUND

Electronic devices with display functions (such as mobile phones and laptops) may conveniently display images, making them widely used in everyday life and work.

Currently, electronic devices with display functions have electronic components arranged in a diffused manner around the edges of the display output area, resulting in a large width outside the edges of the display output area.

### SUMMARY

In one aspect, the present disclosure provides a display screen. The display screen includes: a body, having a first surface including a display output area; and a connection terminal, where the display screen includes M data lines, each corresponding to a column in N display pixel units forming the display output area; the M data lines are arranged to form a first width; the M connection lines are arranged on the display output area; each data line corresponds to a connection line; the M connection lines are arranged to form a second width, the second width being smaller than the first width; the M connection lines extend from the body at the second width and are connected to the connection terminal; the M connection lines are deformable, and both M and N are greater than or equal to 1.

In another aspect, the present disclosure provides an electronic device. The device includes: a main board; and a display screen, the display screen includes: a body, having a first surface including a display output area; and a connection terminal, where the display screen includes M data lines, each corresponding to a column in N display pixel units forming the display output area; the M data lines are arranged to form a first width; the M connection lines are arranged on the display output area; each data line corresponds to a connection line; the M connection lines are arranged to form a second width, the second width being smaller than the first width; the M connection lines extend from the body at the second width and are connected to the connection terminal; the M connection lines are deformable, and both M and N are greater than or equal to 1, and where the display screen is connected to the main board via the connection terminal, where a target portion of the M connection lines that extends from the body at the second width and is connected to the connection terminal is deformable, where a first portion of the M connection lines that extends from the body at the second width and the connection terminal are positioned on a side of a second surface of the body opposite the first surface.

In a third aspect, the present disclosure provides an electronic device. The electronic device includes: a main board; and a display screen connected to the main board, wherein the display screen includes: M data lines, corresponding to display pixel units and arranged to be of a first width; and M connection lines, corresponding to the M data lines and arranged to be of a second width, the second width being smaller than the first width.

### BRIEF DESCRIPTION OF THE DRAWINGS

In order to more clearly illustrate certain embodiments of the present disclosure, the following briefly introduces the drawings for description of certain embodiments. The drawings described below reflect certain embodiments of the present disclosure. For ordinary technicians in the technical field, other drawings may be obtained based on these drawings without any creative work.

FIG. 1 is a schematic diagram of a structure of a display screen according to certain embodiments of the present disclosure;

FIG. 2 is a partial schematic diagram of a display screen according to certain embodiments of the present disclosure;

FIG. 3 is a partial schematic diagram of a display screen according to certain embodiments of the present disclosure;

FIG. 4 is a schematic diagram of an electronic device (first surface side) according to certain embodiments of the present disclosure; and

FIG. 5 is a schematic diagram of an electronic device (second surface side) according to certain embodiments of the present disclosure.

### EXPLANATION OF REFERENCE NUMERALS

10, display screen; 11, body; 12, connection terminal; 13, data line; 14, display pixel unit; 141, red pixel; 142, blue pixel; 143, green pixel; 15, connection line; 16, controller; 17, driver chip; 18, cable; 19, electronic device.

### DETAILED DESCRIPTION

To further clarify the objectives, technical solutions, and advantages of certain embodiments of the present disclosure, the following provides a description of the technical solutions of certain embodiments of the present disclosure, in conjunction with the accompanying drawings. The described embodiments represent only a portion of the embodiments of the present disclosure, and not all of them. Based on the described embodiments of the present disclosure, other embodiments obtained by persons of ordinary skill in the technical field without inventive effort are within the scope of protection of the present disclosure. Therefore, the following detailed description of certain embodiments of the present disclosure, as provided in the accompanying drawings, is not intended to limit the scope of the present disclosure but merely represents certain embodiments of the present disclosure.

The embodiments and features of the embodiments of the present disclosure may be combined unless otherwise stated. The present disclosure is described in detail below with reference to the accompanying drawings.

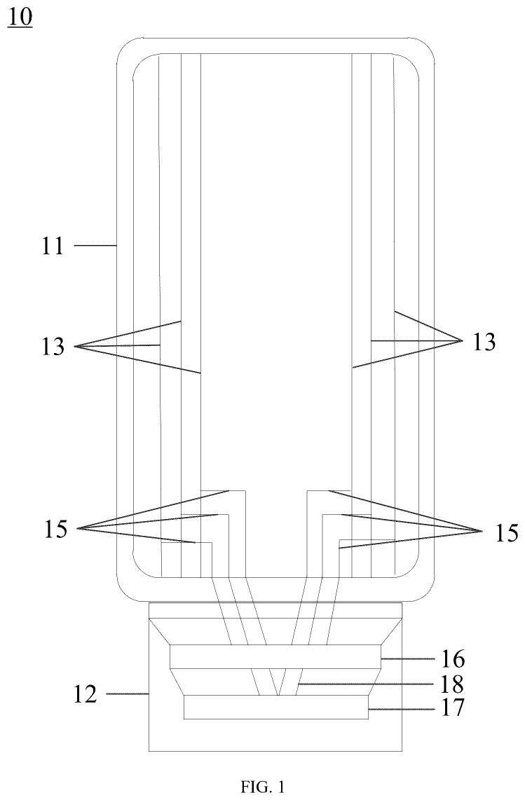

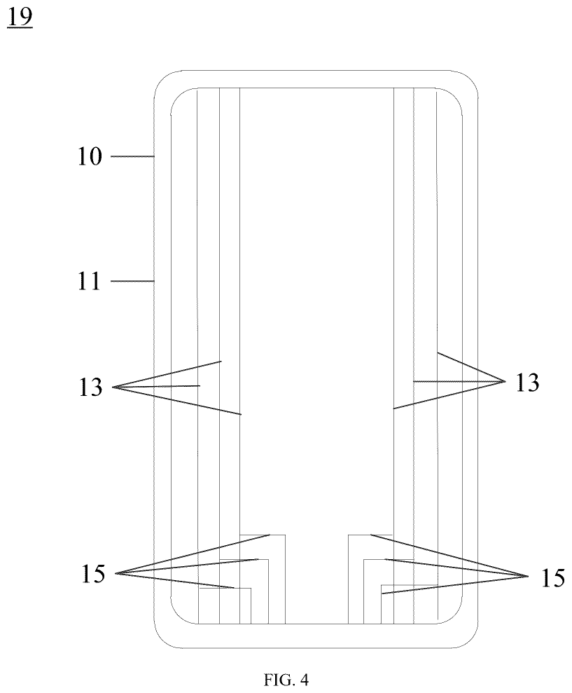

In a first aspect, certain embodiments of the present disclosure provide a display screen 10. Referring to FIGS. 1 to 5, display screen 10 includes a body 11 and a connection terminal 12. Body 11 has a first surface including a display output area. Display screen 10 includes M data lines 13, each corresponding to a column in N display pixel units 14 forming the display output area. The layout of the M data lines 13 forms a first width. Each data line 13 corresponds to a connection line 15, and the layout of the M connection lines 15 forms a second width that is smaller than the first width. The M connection lines 15 extend from body 11 at the second width and connect to connection terminal 12. The M connection lines 15 are deformable, and both M and N are greater than or equal to 1. The M connection lines are arranged on the display output area.

In certain embodiments, the display screen 10 includes an OLED (organic light emitting diode) screen.

In certain embodiments, the display screen 10 may be a display screen on a mobile phone, a tablet computer, or a display screen on another electronic device.

The body 11 includes a first surface including a display output area. That is, the body 11 includes a first surface, and the first surface includes a display output area, and the display output area may display images. The display screen 10 includes M data lines 13, each data line 13 corresponds to a column in N display pixel units 14 forming the display output area, that is, the display output area includes multiple columns of display pixel units 14, and each column of display pixel units 14 includes multiple display pixel units 14. A column of display pixel units 14 is connected to a corresponding data line 13, so that the same data line 13 transmits display information to a column of display pixel units 14. The layout of the M data lines 13 forms a first width. A distance between two opposite surfaces of the outermost two data lines 13 of the M data lines 13 is equal to the first width.

Each data line 13 corresponds to a connection line 15, and the layout of the M connection lines 15 forms a second width, which is smaller than the first width. That is, one data line 13 is connected to a corresponding connection line 15, so that M data lines 13 are connected to M connection lines 15, and the distance between the two opposite surfaces of the outermost two connection lines 15 among the M connection lines 15 is equal to the second width, and the distance between the two opposite surfaces of the outermost two connection lines 15 among the M collection lines 15 is smaller than the distance between the two opposite surfaces of the outermost two data lines 13 among the M data lines 13. For example, referring to FIG. 1, the M connection lines 15 tend to converge from one end connected to the M data lines 13 toward the end away from the M data lines 13.

The M connection lines 15 extend from the body 11 at the second width and are connected to the connection terminal 12. The M connection lines 15 may be deformed, so that at least part of the M connection lines 15 may be bent toward the front side or the back side of the display screen 10.

In certain embodiments, the M connection lines 15 may be deformed so that at least part of the M connection lines 15 may be bent toward the front side or the back side of the display screen 10, so that the connection terminal 12 may be positioned on the front side or the back side of the display screen 10, so as to reduce the number of electronic components outside the edge of the display output area, and further reduce the width outside the edge of the display output area. In addition, since the M connection lines 15 may be deformed, the width of the M connection lines 15 connected to the M data lines 13 may be smaller than the width of the M data lines 13, and the portion of the M connection lines 15 with smaller width may be bent to the front side or back side of the display screen 10 more quickly and conveniently.

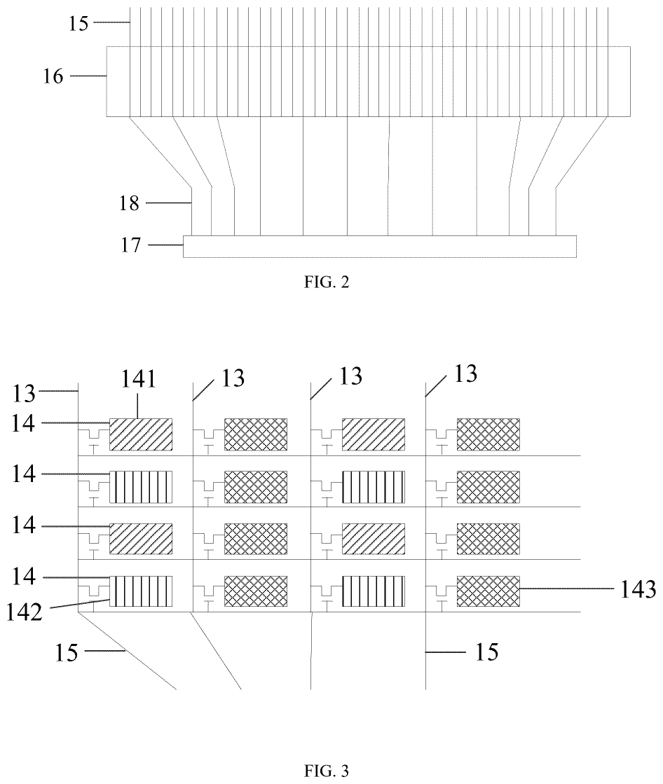

In certain embodiments, as shown in FIGS. 1 and 2, positioned between the M connection lines 15 and the connection terminal 12 include: a controller 16 and a driver chip 17, a first end of the controller 16 is connected to the M connection lines 15, and the driver chip 17 is connected to a second end of the controller 16 through Q cables 18, where Q is less than M.

In certain embodiments, the first end of the controller 16 is connected to the M connection lines 15, and the driver chip 17 is connected to the second end of the controller 16 through the Q cables 18. That is, the two ends of the controller 16 are respectively connected to the M connection lines 15 and the Q cables 18, and the Q cables 18 are all connected to the driver chip 17. In this way, the driver signal of the driver chip 17 may be transmitted to the M connection lines 15 via the Q cables 18 and the controller 16. In the above description, Q is less than M, that is, the driver signal of the driver chip 17 is transmitted to the controller 16 through cables 18 that are relatively smaller in number, and the controller 16 distributes the received driver signal to M connection lines 15 that are relatively larger in number. For example, the controller 16 is a multiplexer, so as to be able to transmit the driver signals of Q cables 18 that are relatively smaller in number to M connection lines 15 that are relatively larger in number. The smaller and larger refer to the number of cables 18 and the number of connection lines 15. Positioned between the M connection lines 15 and the connection terminal 12 include: a controller 16 and a driver chip 17. The first end of the controller 16 is connected to the M connection lines 15, and the driver chip 17 is connected to the second end of the controller 16 through Q cables 18. In certain embodiments, the M connection lines 15 connected to the controller 16 and the connection terminal 12 are both positioned on the front side or the back side of the display screen 10, so that the controller 16 and the driver chip 17 are positioned on the side of the display screen 10 where the connection terminal 12 is provided.

In certain embodiments, the controller 16 includes a demultiplexer (demux).

In certain embodiments, the driver signal of the driver chip 17 may be transmitted to the connection line 15 through the cable 18 and the controller 16, so that the data line 13 connected to the connection line 15 transmits the driver signal to the corresponding column of display pixel units 14 after receiving the driver signal transmitted by the connection line 15 to realize the change of the state of the column of display pixel units 14. Furthermore, controller 16 and driver chip 17 are positioned on the side of display screen 10 where connection terminal 12 is positioned, further reducing the number of electronic components outside the edge of the display output area, thereby reducing the width of the display output area outside the edge. Furthermore, because the number of cables 18 is less than the number of connection lines 15, the width of the Q cables 18 may be less than the width of the M connection lines 15, thereby reducing the space occupied by the Q cables 18. Furthermore, since the number of cables 18 is less than the number of connection lines 15, the manufacturing cost of the display screen 10 may be reduced.

Changes in the state of the display pixel unit 14 include, but are not limited to, lighting up, increasing brightness, decreasing brightness, and flashing the display pixel unit 14.

In certain embodiments, each cable 18 corresponds to at least two connection lines 15. For example, as shown in FIG. 2, each cable 18 corresponds to four connection lines 15.

In a second aspect, certain embodiments of the present disclosure provide an electronic device 19, as shown in FIGS. 1 to 5. The electronic device 19 includes a main board and a display screen 10. The display screen 10 includes a body 11 and a connection terminal 12. The body 11 has a first surface including a display output area, and the connection terminal 12 is connected to the main board. The display screen 10 includes M data lines 13, each data line 13 corresponding to a column in N display pixel units 14 constituting the display output area. The layout of the M data lines 13 forms a first width. Each data line 13 corresponds to a connection line 15. The layout of the M connection lines 15 forms a second width, which is smaller than the first width. M connection lines 15 extend from the body 11 at the second width and are connected to the connection terminal 12. The M connection lines 15 are deformable, and both M and N are greater than or equal to 1. The display screen 10 is connected to the main board via the connection terminal 12. A target portion of the M connection lines 15 extending from the body 11 at the second width and connected to the connection terminal 12 is deformed. A first portion of the M connection lines 15 extending from the body 11 at the second width and the connection terminal 12 are positioned on a side of a second surface of the body 11 opposite the first surface.

In certain embodiments, the electronic device 19 may be a mobile phone, a tablet computer, or other electronic devices. The body 11 of the display screen 10 is connected to the main board via the connection terminal 12, so that data may be transmitted between the main board and the display screen 10 via the connection terminal 12. For example, display data may be transmitted between the main board and the display screen 10 via the connection terminal 12, so that the display output area of the display screen 10 displays according to the received display data. The target portion and the first portion described above are each a portion of the M connection lines 15. For example, the target portion is connected to the first portion, and the target portion is deformed so that the first portion and the connection terminal 12 are positioned on the side of the second surface of the body 11 opposite the first surface. Here, the first surface of the body 11 is the surface having the display output area, and the second surface of the body 11 corresponds to the back surface of the display screen 10.

In certain embodiments, the width of M connection lines 15 is smaller than the width of M data lines 13. When the connection terminal 12 is flipped from the front side of the display screen to the back side of the display screen 10, the space occupied by the connection terminal 12 is smaller. The electronic device may be a mobile phone or tablet computer. Because the first portion of the M connection lines 15 is closer to the edge of the display output area when the first portion is flipped to the back side of the display screen 10, the distance from the display output area to the edge of the electronic device, such as a mobile phone or tablet computer, is thus shorter. Accordingly, the electronic device provided by embodiments of the present application has a smaller/narrower chin area.

In certain embodiments, the controller 16 includes a demux controller, such as a 1:2 demux controller. In certain embodiments, the driver chip 17 includes a driver IC.

In certain embodiments, by setting the above-mentioned display screen 10 on the electronic device 19, so that the first portion of the M connection lines 15 outside the edge of the display output area of the display screen 10 and the connection terminal 12 are positioned on the side of the second surface of the body 11 opposite to the first surface, the number of electronic components outside the edge of the display output area may be reduced, and the width of the frame of the electronic device 19 may be reduced.

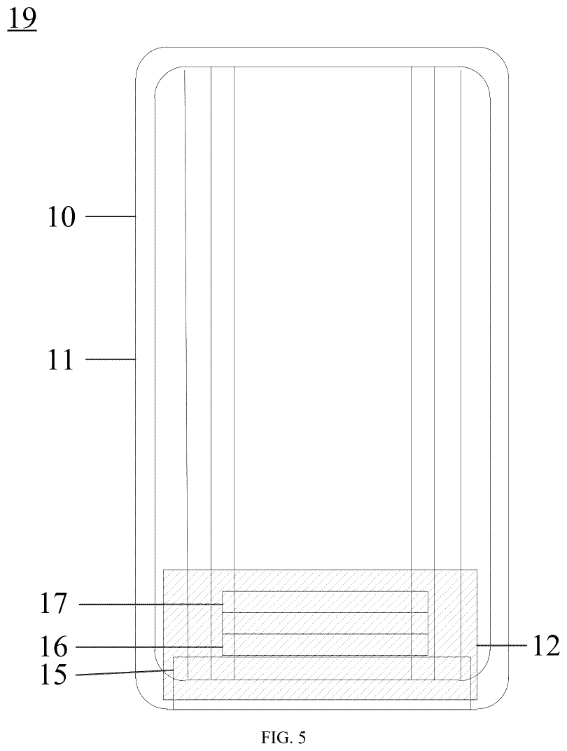

In certain embodiments, as shown in FIG. 5, positioned between the M connection lines 15 and the connection terminal 12 include: a controller 16 and a driver chip 17. The first end of the controller 16 is connected to the first portion of the M connection lines 15. The driver chip 17 is connected to the second end of the controller 16 via Q cables 18, where Q is less than M. Here, since the first portion is positioned on the side of the second surface of the body 11 opposite to the first surface, the controller 16 is connected to the first portion, and the driver chip 17 is connected to the second end of the controller 16 through the Q cable 18, so that the controller 16, the Q cable 18 and the driver chip 17 are all positioned on the side of the second surface of the body 11 opposite to the first surface, thereby further reducing the number of electronic components outside the edge of the display output area, and thus reducing the width of the frame of the electronic device 19.

In certain embodiments, each cable 18 corresponds to at least two connection lines 15. For example, as shown in FIG. 2, each cable 18 corresponds to four connection lines 15.

In certain embodiments, as shown in FIG. 2, the controller 16 receives a source signal from each cable 18 and converts it into a first control signal for the first connection line and a second control signal for the second connection line. In other words, a source signal received by the controller 16 from any cable 18 is converted into a first control signal for the first connection line and a second control signal for the second connection line, thereby distributing signals from Q cables 18 to M connection lines 15, where Q is less than M.

In certain embodiments, as shown in FIG. 3, a column of display pixel units 14 connected in series by a first connection line includes red pixels 141 and blue pixels 142, and a column of display pixel units 14 connected in series by a second connection line includes green pixels 143. Here, the first connection line is one of the M connection lines 15, and the second connection line is another of the M connection lines 15. The first connection line and the second connection line may be two adjacent connection lines 15, or may be two non-adjacent connection lines 15. For example, referring to FIG. 3, the first connection line and the second connection line are adjacent, a column of display pixel units 14 connected in series with the first connection line includes red pixels 141 and blue pixels 142, and a column of display pixel units 14 connected in series with the second connection line includes green pixels 143.

In certain embodiments, as shown in FIG. 5, the first portion of the M connection lines 15 forms the first connection region of the display screen 10, and the first connection region is positioned on the side of the second surface of the body 11 opposite the first surface. In other words, the first portion of the M connection lines 15 is positioned on the side of the second surface of the body 11 opposite the first surface. This reduces the number of electronic components outside the edge of the display output area, thereby reducing the width of the frame of the electronic device 19. Here, the first connection region may correspond to the display output area.

In certain embodiments, as shown in FIG. 5, Q cables 18 form a second connection region of the display screen 10, positioned on the side of the second surface of body 11 opposite the first surface. In other words, the Q cables 18 are positioned on the side of the second surface of body 11 opposite the first surface. This reduces the number of electronic components outside the edge of the display output area, thereby reducing the width of the frame of electronic device 19. Here, the second connection region may correspond to the display output area.

The display screen in the electronic device provided in certain embodiments of the present disclosure is similar to the display screen described above in certain embodiments of the present disclosure and has similar beneficial effects as the display screen embodiments. For technical details not disclosed in the electronic device embodiments of the present disclosure, reference may be made to the description of the display screen embodiments in the present disclosure, and repeat description is avoided for brevity.

### Examples.

With reference to FIGS. 1 to 5, the electronic device 19 includes a main board and a display screen 10.

The display screen 10 includes a body 11 and a connection terminal 12. The body 11 includes a first surface including a display output area. The connection terminal 12 is connected to the main board. The display screen 10 includes M data lines 13. Each data line 13 corresponds to a column in N display pixel units 14 constituting the display output area. The layout of the M data lines 13 forms a first width. Each data line 13 corresponds to a connection line 15. The layout of the M connection lines 15 forms a second width. The second width is smaller than the first width. M connection lines 15 extend from the body 11 at the second width and are connected to the connection terminal 12. The M connection lines 15 are deformable, and both M and N are greater than or equal to 1. Positioned between the M connection lines 15 and the connection terminal 12 include a controller 16 and a driver chip 17. The first end of the controller 16 is connected to the first portion of the M connection lines 15. The driver chip 17 is connected to the second end of the controller 16 via Q cables 18, where Q is less than M. Each cable 18 corresponds to at least two connection lines 15. The controller 16 receives a source signal from each cable 18 and converts it into a first control signal for the first connection line and a second control signal for the second connection line. The display pixel units 14 in a column connected in series with the first connection line include red pixels 141 and blue pixels 142, and the display pixel units 14 in a column connected in series with the second connection line include green pixels 143. The first portion of the M connection lines 15 forms a first connection region of the display screen 10, which is positioned on a side of the second surface of the body 11 opposite the first surface. The Q cables 18 form a second connection region of the display screen 10, which is positioned on a side of the second surface of the body 11 opposite the first surface.

The display screen 10 is connected to the main board via the connection terminal 12. The M connection lines 15 extending from the body 11 at the second width are deformed at the target portion for connection with the connection terminal 12. The first portion of the M connection lines 15 extending from the body 11 at the second width and the connection terminal 12 are positioned on a side of the second surface of the body 11 opposite the first surface.

In certain embodiments, by bending the connection lines 15 toward the second surface of the display screen 10, such that a portion of the connection lines 15, the controller 16 connected thereto, the driver chip 17, and the cable 18 may be positioned on the second surface of the display screen 10. This reduces the number of electronic components outside the edge of the display output area, thereby reducing the width of the frame of the electronic device 19.

In the description of the present disclosure, the terms “first” and “second” are used for descriptive purposes only and should not be construed to indicate or imply relative importance or implicitly specify the number of technical features indicated. Therefore, features referred to as “first” or “second” may explicitly or implicitly include at least one of such features.

In addition, in the description of the present disclosure, terms such as “longitudinal,” “horizontal,” “upper,” “lower,” “front,” “rear,” “left,” “right,” “vertical,” “horizontal,” “top,” “bottom,” “inner,” “outer,” “axial,” and “radial” to indicate orientations or positional relationships are based on the orientations or positional relationships shown in the accompanying drawings and are intended solely to facilitate the description of the present disclosure and simplify the description. They are not intended to indicate or imply that the devices or components referred to must have, be constructed, or operate in a particular orientation and should not be construed as limitations on the present disclosure.

In addition, in the present disclosure, unless otherwise clearly stated and limited, the terms “connection”, “connected”, or the like should be understood in a broad sense. For example, it may be a mechanical connection or an electrical connection; it may be a direct connection or an indirect connection through an intermediate medium; it may be an internal connection between two elements or an interaction relationship between two elements. Unless otherwise clearly stated, ordinary technicians in the technical field may understand the meanings of the above terms in the present disclosure according to certain circumstances.

The described embodiments reflect the technical solutions of the present disclosure, and are not to necessarily limit the scope of the present disclosure. Although the present disclosure has been described in detail with reference to certain embodiments, those skilled in the technical field understand that they may still modify the technical solutions described in the aforementioned embodiments, or make equivalent replacements for some or all of the technical features therein. These modifications or replacements do not deviate the essence of the corresponding technical solutions from the scope of the technical solutions of the embodiments of the present disclosure.

What is claimed is:

1. A display screen, comprising:
a body, having a first surface including a display output area; and
a connection terminal,
wherein the display screen includes M data lines, each corresponding to a column in N display pixel units forming the display output area; the M data lines are arranged to form a first width; each data line corresponds to a connection line; the M connection lines are arranged to form a second width, the second width being smaller than the first width; the M connection lines are arranged on the display output area; the M connection lines extend from the body at the second width and are connected to the connection terminal; the M connection lines are deformable, and both M and N are greater than or equal to 1.

2. The display screen of claim 1, wherein positioned between the M connection lines and the connection terminal include:
a controller, including a first end connected to the M connection lines; and
a driver chip, being connected to a second end of the controller via Q cables, where Q is less than M.

3. The display screen of claim 2, wherein each cable corresponds to at least two connection lines.

4. An electronic device, comprising: a main board; and a display screen, the display screen including:
a body, having a first surface including a display output area; and
a connection terminal,
wherein the display screen includes M data lines, each corresponding to a column in N display pixel units forming the display output area; the M data lines are arranged to form a first width; each data line corresponds to a connection line; the M connection lines are arranged to form a second width, the second width being smaller than the first width; the M connection lines are arranged on the display output area; the M connection lines extend from the body at the second width and are connected to the connection terminal; the M connection lines are deformable, and both M and N are greater than or equal to 1, and
wherein the display screen is connected to the main board via the connection terminal, wherein a target portion of the M connection lines that extends from the body at the second width and is connected to the connection terminal is deformable, wherein a first portion of the M connection lines that extends from the body at the second width and the connection terminal are positioned on a side of a second surface of the body opposite the first surface.

5. The electronic device of claim 4, wherein positioned between the M connection lines and the connection terminal include:
a controller, including a first end connected to the first portion of the M connection lines; and
a driver chip, connected to a second end of the controller via Q cables, where Q is less than M.

6. The electronic device of claim 5, wherein each cable corresponds to at least two connection lines.

7. The electronic device of claim 6, wherein the controller receives a source signal from each of the cables and converts the source signal into a first control signal for the first connection line and a second control signal for the second connection line.

8. The electronic device of claim 7, wherein a column of display pixel units connected in series with the first connection line includes red pixels and blue pixels, and a column of display pixel units connected in series with the second connection lines includes green pixels.

9. The electronic device of claim 5, wherein
a first portion of the M connection lines forms a first connection region for the display screen, and the first connection region is positioned on a side of a second surface of the body opposite to the first surface.

10. The electronic device of claim 5, wherein the Q cables form a second connection region for the display screen, and the second connection region is positioned on a side of a second surface of the body opposite the first surface.

11. An electronic device, comprising: a main board; and a display screen connected to the main board, wherein the display screen includes:
M data lines, corresponding to display pixel units and arranged to be of a first width; and
M connection lines, corresponding to the M data lines and arranged to be of a second width, the second width being smaller than the first width.

12. The electronic device of claim 11, wherein the M data lines extend in a longitudinal direction, and a portion of the M connection lines extend in a width direction, and the width direction is at an angle to the longitudinal direction.

13. The electronic device of claim 11, further comprising:
a connection terminal, wherein a portion of the M connection lines enters the connection terminal.

14. The electronic device of claim 13, wherein the display screen is connected to the main board via the connection terminal.

15. The electronic device of claim 13, further comprising:
a controller, at least partially positioned within the connection terminal.

16. The electronic device of claim 13, further comprising:
a drive chip, at least partially positioned within the connection terminal.

17. The electronic device of claim 13, further comprising:
Q cables, at least partially positioned within the connection terminal.

18. The electronic device of claim 17, wherein Q is smaller than M.

19. The electronic device of claim 17, wherein the Q cables are arranged to be of a third width, the third width being smaller than the second width.

20. The electronic device of claim 13, further comprising:
a controller, at least partially positioned within the connection terminal;
a drive chip, at least partially positioned within the connection terminal; and
Q cables, at least partially positioned within the connection terminal, wherein the controller is positioned between the M data lines and the driver chip.
